(19) United States
(12) Patent Application Publication
(10) Pub. No.: US 2013/0104970 A1
(43) Pub. Date: May 2, 2013

(54) FOUR JUNCTION SOLAR CELL

(71) Applicant: FLORIDA STATE UNIVERSITY RESEARCH FOU, Tallahassee, FL (US)

(72) Inventors: Indranil Bhattacharya, Tallahassee, FL (US); Simon Y. Foo, Tallahassee, FL (US)

(73) Assignee: FLORIDA STATE UNIVERSITY RESEARCH FOUNDATION, INC., Tallahassee, FL (US)

(21) Appl. No.: 13/651,969

(22) Filed: Oct. 15, 2012

Related U.S. Application Data
(60) Provisional application No. 61/547,303, filed on Oct. 14, 2011.

(51) Int. Cl. H01L 31/0304

(52) U.S. Cl. CPC H01L 31/03046
USPC 136/255

(57) ABSTRACT

A four-junction solar cell including a first layer comprised of AlGaInP, a second layer comprised of InGaAs, a third layer comprised of GaSb, a fourth layer comprised of InGaSb, a first tunnel junction disposed between the first and second layers, a second tunnel junction disposed between the second and third layers, and a third tunnel junction disposed between the third and fourth layers. Alternately, the four-junction solar cell includes AlGaInP as the top layer, InGaP as the second layer, InGaAs as the third layer and InGaSb as the bottom layer. Tunnel junctions are disposed in between each layer. An alternate solar cell design includes AlGaInP/GaAs/InGaAs/InGaSb layers.

### CROSS-REFERENCE TO RELATED APPLICATIONS

This Application claims priority to U.S. Provisional Patent Application No. 61/547,303, filed Oct. 14, 2011, entitled FOUR JUNCTION SOLAR CELL, the entirety of which is incorporated herein by reference.

### STATEMENT REGARDING FEDERALLY SPONSORED RESEARCH OR DEVELOPMENT

N/A

### FIELD OF THE INVENTION

The present disclosure relates to solar cells and in particular a quadruple-junction solar cell having AlGaInP/InGaP/InGaAs/InGaSb or AlGaInP/InGaAs/GaSb/InGaSb materials.

### BACKGROUND OF THE INVENTION

Existing solar cells do not provide adequate photon absorption. Many typical solar cells utilize indirect bandgap germanium (Ge) layers as part of a triple-layer cell. This results in a loss of energy due to indirect transfer of electrons from the valence band to the conduction band through the creation of a phonon particle.

In addition, germanium is expensive resulting in a solar cell that is not cost-effective.

Therefore, what is needed is a four-junction solar cell that provides higher photon absorption than the typical three-junction solar cells in today's market and that is also cost-effective.

### SUMMARY OF THE INVENTION

Disclosed herein is a four-junction solar cell having a higher photon absorption than typical triple-junction solar cells. The combination of subcell layers further discussed below effectively splits the solar radiation spectrum resulting in higher photon absorption.

The semiconductor materials used to design the subcells of the four-junction solar cell disclosed herein are direct bandgap semiconductors unlike the indirect bandgap germanium (Ge) layers used in typical solar cells. For direct bandgap semiconductors, the momentum of electrons in the valence band and conduction band are the same so the electrons can jump directly from the valence band to the conduction band unlike the indirect bandgap Ge layer. Some energy is lost due to indirect transfer of electrons from valence to conduction band through creation of phonon particle in case of Ge.

In one aspect of the invention, the solar cell includes a first layer comprised of AlGaInP, a second layer comprised of InGaAs, a third layer comprised of GaSb, a fourth layer comprised of InGaSb, a first tunnel junction disposed between the first and second layers, a second tunnel junction disposed between the second and third layers, and a third tunnel junction disposed between the third and fourth layers.

In another aspect of the invention, the solar cell includes a first layer comprised of AlGaInP, a second layer comprised of InGaP, a third layer comprised of InGaAs, a fourth layer comprised of InGaSb, a first tunnel junction disposed between the first and second layers, a second tunnel junction disposed between the second and third layers, and a third tunnel junction disposed between the third and fourth layers.

In another aspect, the solar cell includes a first layer comprised of AlGaInP, a second layer comprised of GaAs, a third layer comprised of InGaAs, a fourth layer comprised of InGaSb, a first tunnel junction disposed between the first and second layers, a second tunnel junction disposed between the second and third layers, and a third tunnel junction disposed between the third and fourth layers.

### BRIEF DESCRIPTION OF THE DRAWINGS

FIG. 1 is a cross-sectional view of a quadruple junction solar cell in accordance with an embodiment of the present invention;

FIG. 2 is a cross-sectional view of a quadruple junction solar cell in accordance with an alternate embodiment of the present invention;

FIG. 3 is a cross-sectional view of a quadruple junction solar cell in accordance with yet another embodiment of the present invention;

FIG. 4 is a cross-sectional view of a quadruple junction solar cell in accordance with still another embodiment of the present invention;

FIG. 5 is a cross-sectional view of a quadruple junction solar cell in accordance with a further embodiment of the present invention;

FIG. 6 is a graphical representation of the photon absorption efficiency of an embodiment of the four junction solar cell of the present invention including aluminum gallium indium phosphide (AlGaInP)/indium gallium phosphide (InGaP)/indium gallium arsenide (InGaAs)/indium gallium antimonide (InGaSb) semiconductor materials;

FIG. 7 is a graphical view comparing the photon absorption efficiency of the four-junction solar cell of FIG. 6 with a crystalline silicon solar cell and with a cadmium telluride (CdTe) solar cell;

FIG. 8 is a graphical view comparing the photon absorption efficiency of the four-junction solar cell of FIG. 6 with an aluminum gallium arsenide (AlGaAs)/gallium arsenide (GaAs) two-junction solar cell;

FIG. 9 is a graphical view comparing the photon absorption efficiency of the four-junction solar cell of FIG. 6 with an aluminum gallium arsenide (InGaAs)/gallium arsenide (GaAs)/indium gallium arsenide (InGaAs) triple-junction solar cell;

FIG. 10 is a graphical view comparing the photon absorption efficiency of the four-junction solar cell of FIG. 6 with a gallium indium phosphide (GaInP)/gallium indium arsenide (GaInAs)/germanium (Ge) triple-junction solar cell;

FIG. 11 is a graphical view of the photon absorption efficiency of an alternate embodiment of the four junction photovoltaic cell of the present invention including aluminum gallium indium phosphide (AlGaInP)/indium gallium arsenide (InGaAs)/gallium antimonide (GaSb)/indium gallium antimonide (InGaSb) semiconductor materials;

FIG. 12 is a graphical view comparing the photon absorption efficiency of the four-junction solar cell of FIG. 11 with a crystalline silicon solar cell and with a cadmium telluride (CdTe) solar cell;

FIG. 13 is a graphical view comparing the photon absorption efficiency of the four-junction solar cell of FIG. 11 with an aluminum gallium arsenide (AlGaAs)/gallium arsenide (GaAs) two-junction solar cell;

FIG. 14 is a graphical view comparing the photon absorption efficiency of the four-junction solar cell of FIG. 11 with an aluminum gallium arsenide (AlGaAs)/gallium arsenide (GaAs)/indium gallium arsenide (InGaAs) triple-junction solar cell;

FIG. 15 is a graphical view comparing the photon absorption efficiency of the four-junction solar cell of FIG. 11 with a gallium indium phosphide (GaInP)/gallium indium arsenide (GaInAs)/germanium (Ge) triple-junction solar cell;

FIG. 16 is a graphical view comparing the photo absorption efficiency of the four-junction solar cell of FIG. 11 with an aluminum gallium indium phosphide (AlGaInP)/aluminum gallium indium arsenide (AlGa(In)As/gallium indium arsenide(Ga(In)As/germanium (Ge) four-junction solar cell.

FIG. 17 is a graphical view of the photon absorption efficiency of yet another embodiment of the four junction photovoltaic cell of the present invention including aluminum gallium indium phosphide (AlGaInP)/gallium arsenide (GaAs)/indium gallium arsenide (InGaAs)/indium gallium antimonide (InGaSb) semiconductor materials.

### DETAILED DESCRIPTION OF THE INVENTION

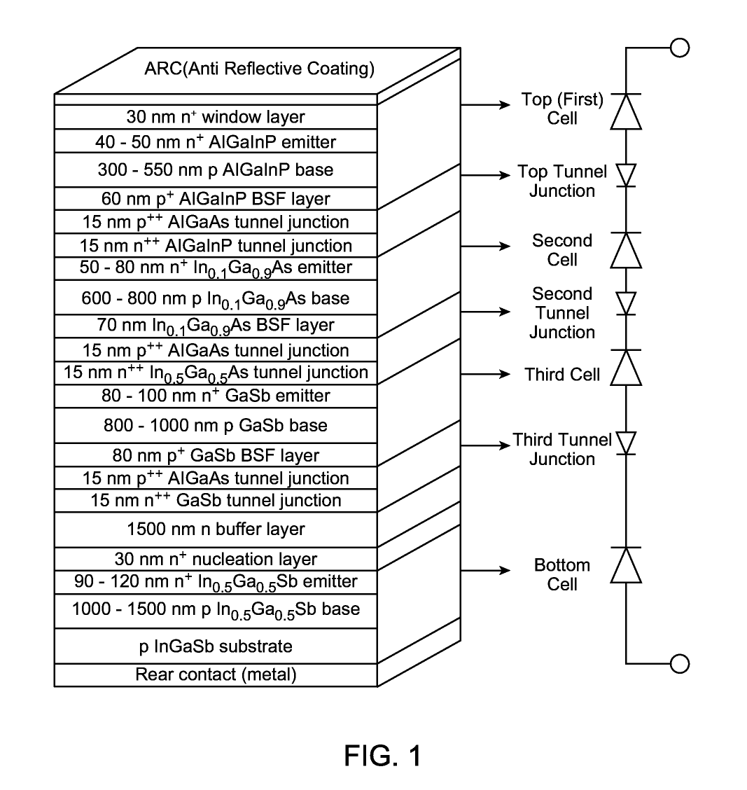

The invention is drawn to a photovoltaic cell, also referred to as a solar cell, with improved absorption of electromagnetic radiation over the entire solar spectrum. The solar cell of the present invention includes a first or top layer (also referred to as “first or top cell”), a second layer (or “second cell”), a third layer (or “third cell”) and a fourth or bottom layer (also referred to as a “fourth cell” or “bottom cell”), where each layer is separated by tunnel junctions, as shown in FIG. 1. A tunnel junction forms the ohmic electrical contact between consecutive solar cells layers for the purpose of passing electrons from one material to the other.

As used herein, the term “cell,” e.g., “first cell,” “second cell,” or “layer”, is used to describe one or more semiconductor layers for absorbing electromagnetic radiation having a targeted band-gap energy, where the cell or layer is bound above and below by an antireflective coating, a tunnel, a passivation layer, a confinement layer, or a cladding layer. The cells act to create electron-hole pairs when illuminated by light.

As used herein, the term “tunnel” is used to describe heavily doped p⁺-n⁺ junctions between cells indicating tunneling phenomena between the solar cell layers. Tunnels are used to make electrical, optical and/or mechanical connections between cells.

In the embodiment of FIG. 1, the top layer can be composed of aluminum gallium indium phosphide (AlGaInP), the second layer can be composed of indium gallium arsenide (InGaAs), the third layer can be composed of gallium antimony (GaSb), and the fourth layer can be composed of indium gallium antimonide (InGaSb). On top of the first layer is an anti-reflective coating (“ARC”) such as Magnesium Oxide and Titanium Oxide (MgO₂+TiO₂) or Indium-Tin Oxide+MgF₂. A rear metal contact is formed on the bottom of the substrate, i.e. below the bottom layer. FIG. 1 also shows an electrical circuit that is equivalent to the quadruple-junction photovoltaic cell layer depiction.

In the embodiment shown in FIG. 1, the top layer can include a 30 nm n⁺ window layer, an n⁺ AlGaInP emitter having a thickness between 40 and 50 nm and a p-type AlGaInP base having a thickness between 300 and 550 nm. The second layer can include an n⁺ In_{0.1}Ga_{0.9}As emitter with a thickness between 50 and 80 nm, a p-type In_{0.1}Ga_{0.9}As base with thickness between 600 and 800 nm and a back surface field (“BSF”) layer, which in one embodiment is 70 nm and composed of In_{0.1}Ga_{0.9}As. The BSF layer provides confinement to the photogenerated minority carriers and keep them within the reach of p/n junctions to be efficiently collected. The third layer can include an n⁺ GaSb emitter having a thickness between 80 and 100 nm and a p-type GaSb base having a thickness between 800 and 1,000 nm. The bottom layer can include a 30 nm n⁺ nucleation layer upon which is disposed an n⁺ In_{0.5}Ga_{0.5}Sb emitter having a thickness 90 and 120 nm and an In_{0.5}Ga_{0.5}Sb base having a thickness between 1,000 and 1,500 nm. The emitter and base are disposed upon a p-type GaAs/InGaSb/GaSb substrate.

The top tunnel junction separating the top layer from the second layer is comprised of a 15 nm p⁺⁺ AlGaAs tunnel junction on top of a 15 nm n^{++ AlGaInP tunnel junction. The second tunnel junction separating the second layer from the third layer may include a} 15 nm p⁺⁺ AlGaAs tunnel junction on top of a 15 nm n⁺⁺ In_{0.5}Ga_{0.5}As tunnel junction. The third tunnel junction separating the second layer and the bottom layer may be composed of a 15 nm p⁺⁺ AlGaAs tunnel junction on top of a 15 nm n⁺⁺ GaSb tunnel junction. A 1,500 nm buffer may separate the third tunnel junction and the bottom layer.

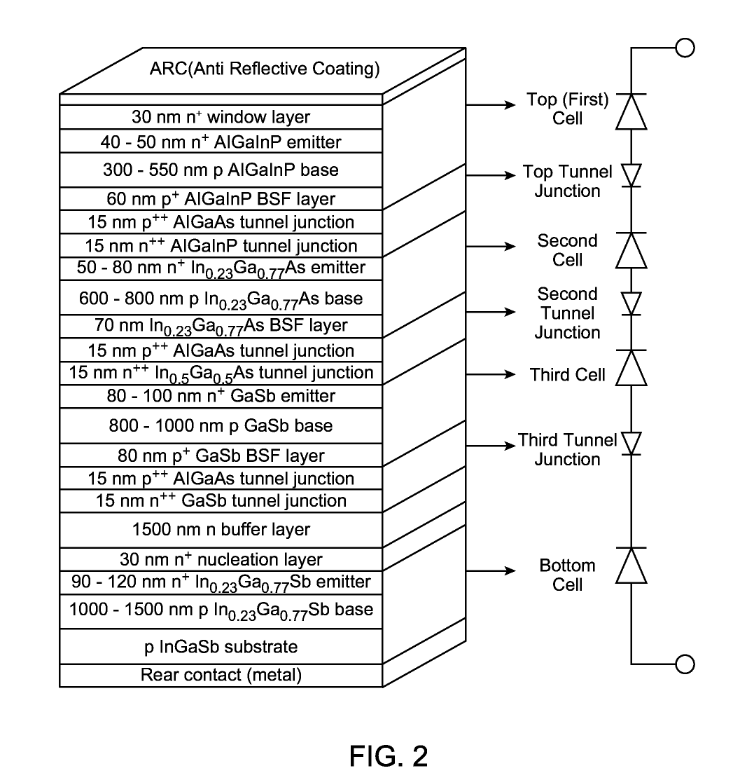

In FIG. 2, an alternate embodiment of the present invention is shown. The substrate shown in FIG. 2 includes the same materials as the embodiment of FIG. 1, but with slightly different dimensions. For example, in the second layer, the emitter is composed of In_{0.23}Ga_{0.77}As and the base is composed of In_{0.23}Ga_{0.77}As. The second tunnel junction, i.e. the junction between the second layer and the third layer is composed of a 70 nm BSF layer of In_{0.23}Ga_{0.77}As. The bottom layer may include an n⁺ emitter composed of In_{0.23}Ga_{0.77}Sb and a base composed of In_{0.23}Ga_{0.77}Sb.

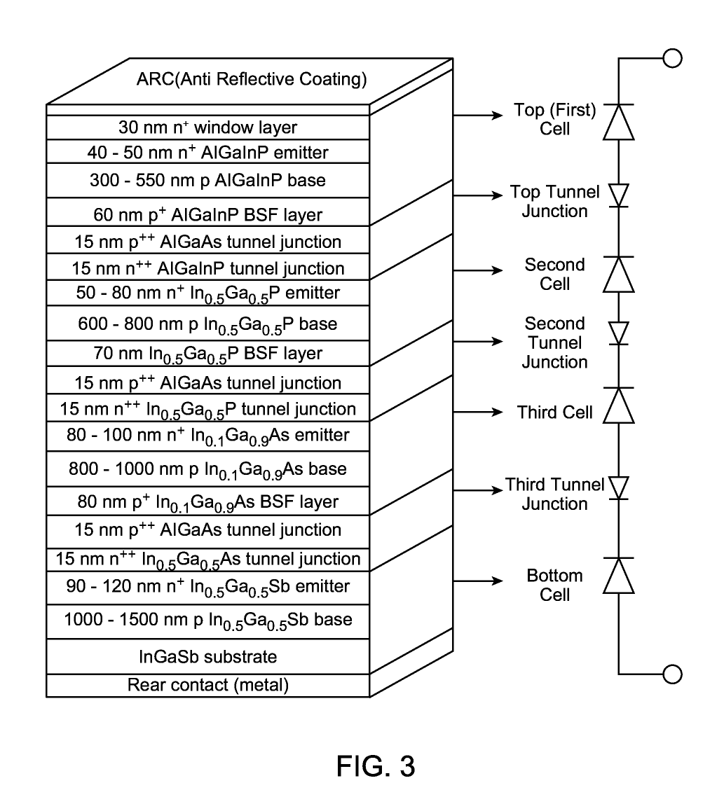

The photovoltaic cell depicted in FIG. 3 represents another embodiment of the present invention. In this embodiment, the materials forming the substrate are different than the materials forming the substrates shown in FIGS. 1 and 2. An ARC resides on top of the substrate and a metal contact resides on the bottom. The top layer is composed of a 30 nm n⁺ window layer, an n⁺ aluminum gallium indium phosphide (AlGaInP) emitter having a thickness of between 40 and 50 nm and an AlGaInP base between 300 and 550 nm in thickness. The second layer is composed of an n⁺ In_{0.5}Ga_{0.5}P emitter having a thickness between 50 and 80 nm, a p-type In_{0.5}Ga_{0.5}P base between 600 and 800 nm and a 70 nm BSF layer composed of In_{0.5}Ga_{0.5}P. The third layer is composed of an n⁺ In_{0.1}Ga_{0.9}As emitter having a thickness between 80 and 100 nm, a p-type In_{0.1}Ga_{0.9}As base between 800 and 1000 nm and an 80 nm p⁺ In_{0.1}Ga_{0.9}As BSF layer. The bottom layer includes an n⁺ In_{0.5}Ga_{0.5}Sb emitter having a thickness between 90 and 120 nm and a p-type In_{0.5}Ga_{0.5}Sb base between 1,000 and 1,500 nm.

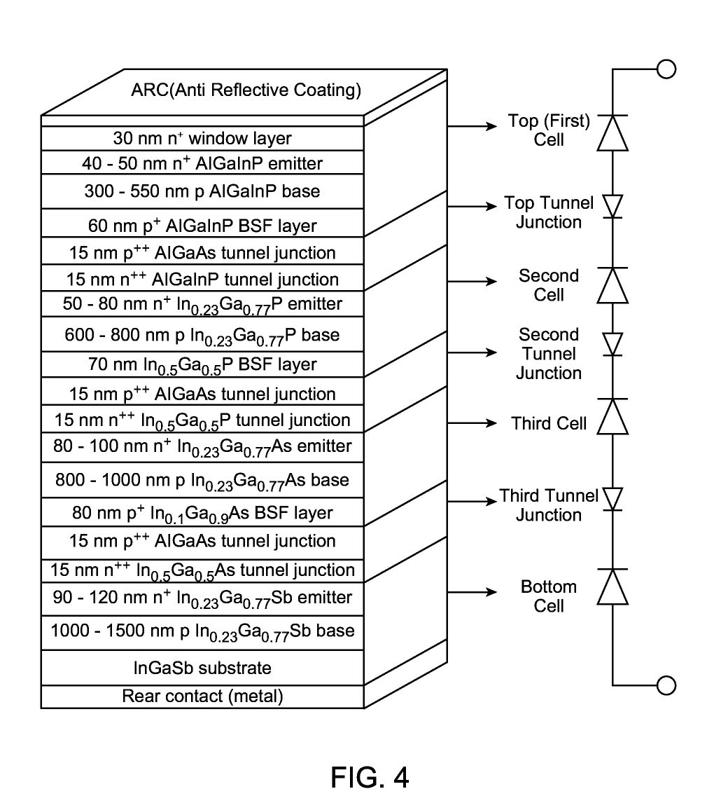

FIG. 4 depicts yet another embodiment of the present invention. The substrate includes the same materials as the substrate shown in FIG. 3 but with different dimensions. For example, the second layer includes an n⁺ In_{0.23}Ga_{0.77}P emitter between 50 and 80 nm, a p-type In_{0.23}Ga_{0.77}P base between 600 and 800 nm and a 70 nm In_{0.23}Ga_{0.77}P BSF layer. The third layer includes an n⁺ In_{0.23}Ga_{0.77}As emitter between 80 and 100 nm, a p-type In_{0.23}Ga_{0.77}As base between 800 and 1,000 nm and an 80 nm p⁺ In_{0.23}Ga_{0.77}As BSF layer. The bottom layer may include an n⁺ In_{0.23}Ga_{0.77}Sb emitter having a thickness between 90 and 120 nm and a p-type In_{0.23}Ga_{0.77}Sb base between 1,000 and 1,500 nm.

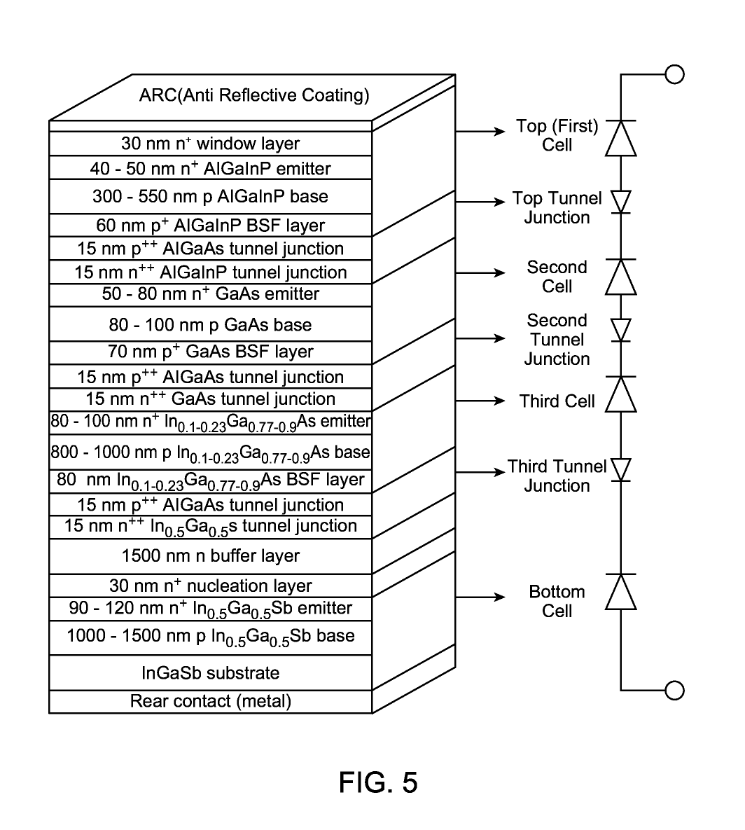

FIG. 5 illustrates still another embodiment of the present invention. The substrate shown in FIG. 5 includes a different composition of materials when compared to the earlier embodiments. For example, the second layer may include an n⁺ GaAs emitter between 50 and 80 nm, a p-type GaAs base between 80 and 100 nm and a 70 nm p⁺ GaAs BSF layer. The second tunnel junction between the second and third layers may include a 15 nm p⁺⁺ AlGaAs tunnel junction disposed upon a 15 nm n⁺⁺ GaAs tunnel junction. The third layer may include an n⁺ In_{0.1-0.23}Ga_{0.77-0.9}AS emitter having a thickness between 80 and100 nm and a p-type In_{0.1-0.23}Ga_{0.77-0.9}AS base between 800 and 1,000 nm. The third tunnel junction between the third and fourth layers may include a 15 nm p⁺⁺ AlGaAs tunnel junction disposed upon a 15 nm n⁺⁺ In_{0.5}Ga_{0.5}As tunnel junction and a 1,500 nm n-type buffer layer. The fourth or bottom layer may include, in addition to a 30 nm n⁺ nucleation layer, an n⁺ In_{0.5}Ga_{0.5}Sb emitter between 90 and 120 nm and a p-type In_{0.5}Ga_{0.5}Sb base between 1,000 and 1,500 nm disposed upon a p-type GaAs/InGaSb substrate.

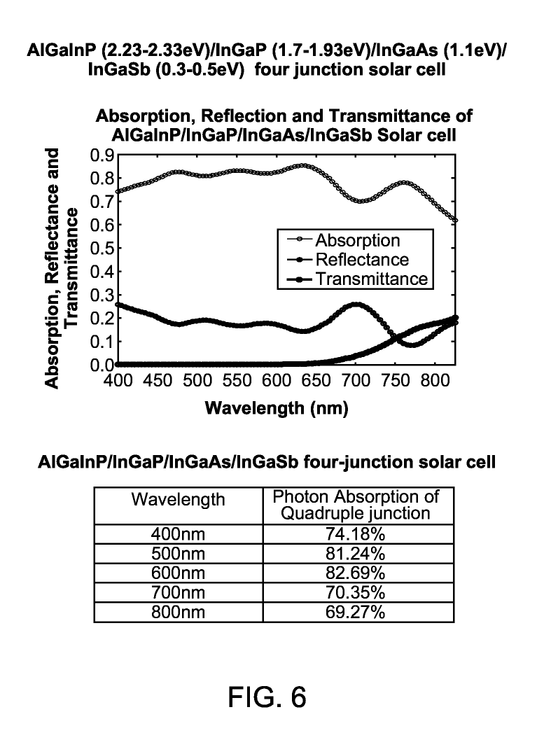

FIG. 6 is a graphical representation of the photon absorption efficiency of an embodiment of the four junction photovoltaic cell of the present invention. The four junctions of the photovoltaic cell are composed of aluminum gallium indium phosphide (AlGaInP) (having a band gap between 2.23 and 2.33 electron volts), indium gallium phosphide (InGaP) (with a band gap between 1.7 and 1.93 electron volts), indium gallium arsenide (InGaAs) (with a band gap of 1.1 electron volts) and indium gallium antimonide (InGaSb) (having a band gap of 0.3 to 0.5 electron volts).

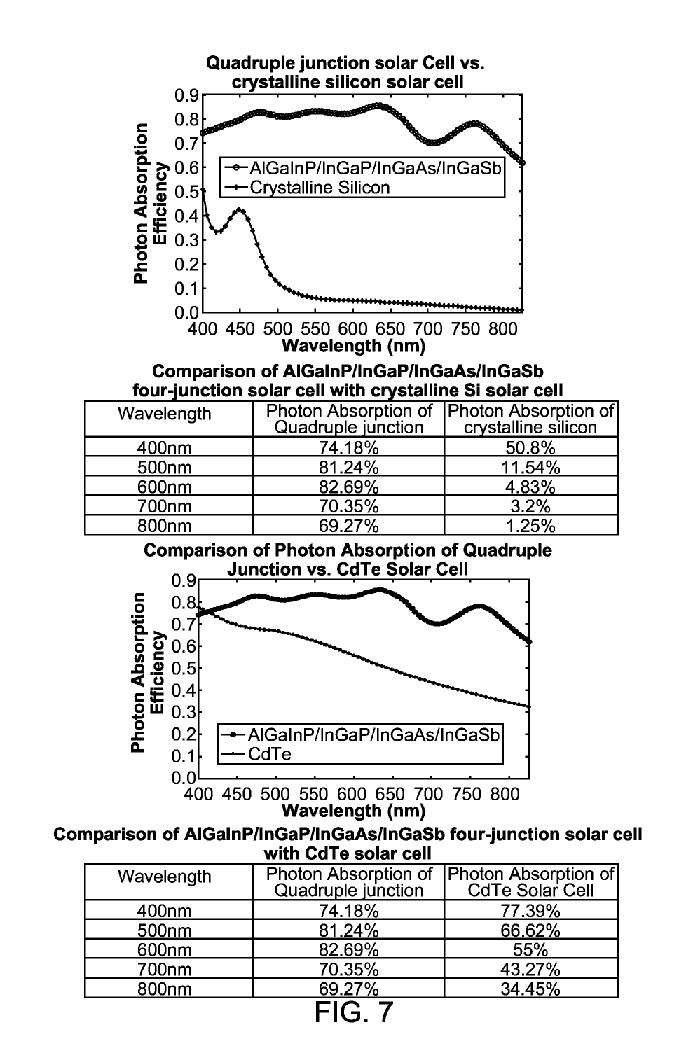

FIG. 7 is a graphical representation comparing the photon absorption efficiency of the four-junction solar cell of FIG. 6 with a crystalline silicon solar cell and with a cadmium telluride (CdTe) solar cell.

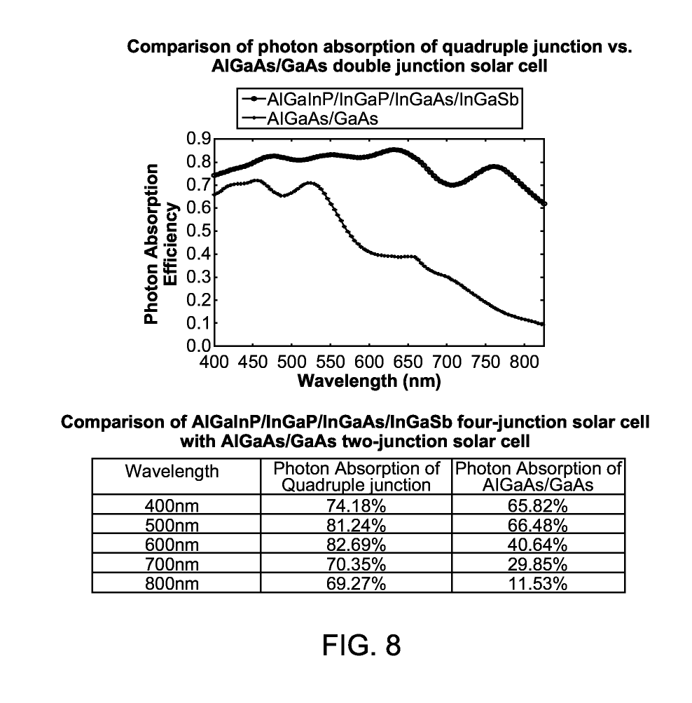

FIG. 8 is a graphical representation comparing the photon absorption efficiency of the four-junction solar cell of FIG. 6 with an aluminum gallium arsenide (AlGaAs)/gallium arsenide (GaAs) two-junction solar cell.

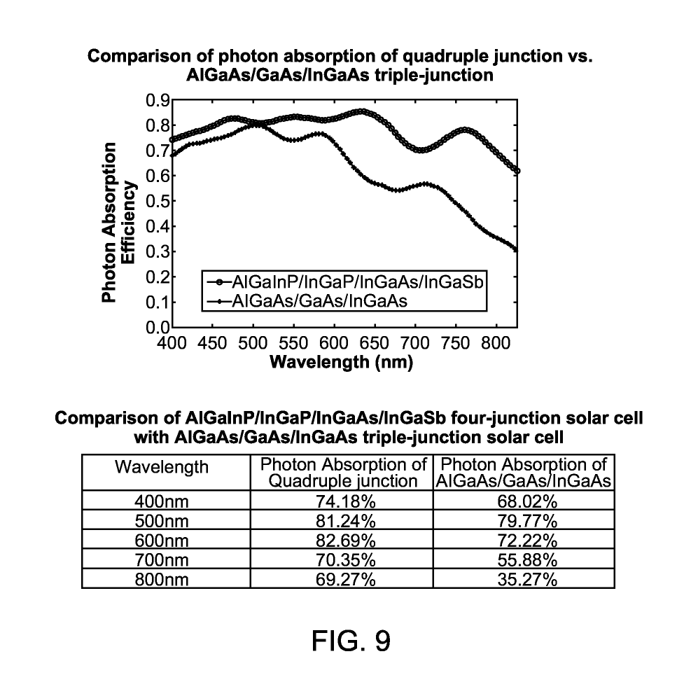

FIG. 9 is a graphical representation comparing the photon absorption efficiency of the four-junction solar cell of FIG. 6 with an aluminum gallium arsenide (InGaAs)/gallium arsenide (GaAs)/indium gallium arsenide (InGaAs) triple-junction solar cell.

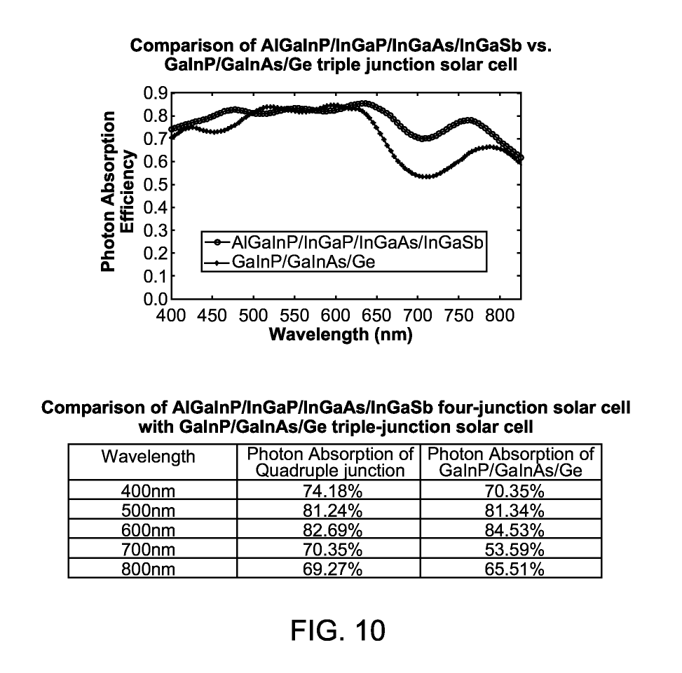

FIG. 10 is a graphical representation comparing the photon absorption efficiency of the four-junction solar cell of FIG. 6 with a gallium indium phosphide (GaInP)/gallium indium arsenide (GaInAs)/germanium (Ge) triple-junction solar cell.

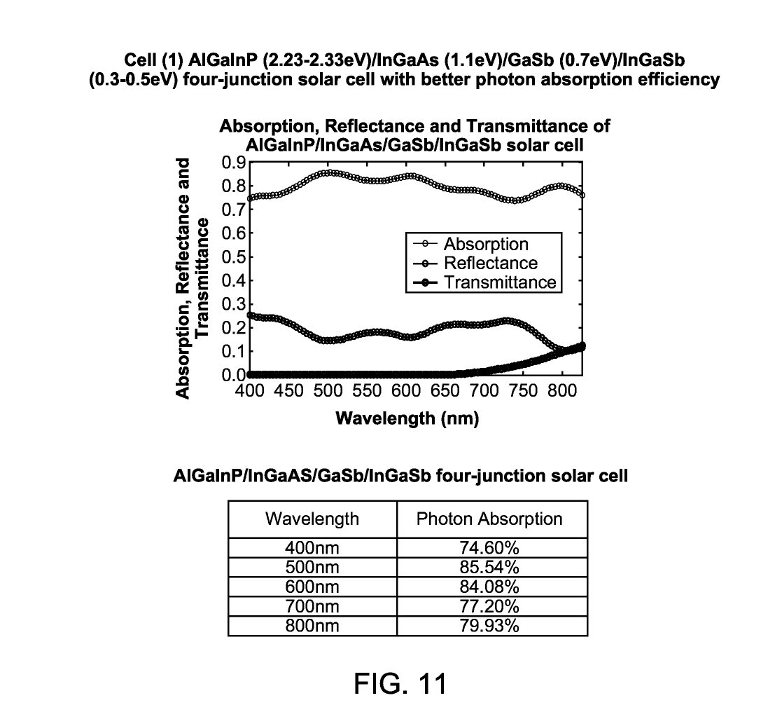

FIG. 11 is a graphical representation of the photon absorption efficiency of an alternate embodiment of the four junction photovoltaic cell of the present invention. The four junctions of the photovoltaic cell are composed of aluminum gallium indium phosphide (AlGaInP) (having a band gap between 2.23 and 2.33 electron volts), indium gallium arsenide (InGaAs) (with a band gap of 1.1 electron volts), gallium antimony (GaSb) (with a band gap of 0.7 electron volts) and indium gallium antimony (InGaSb) (having a band gap of 0.3 to 0.5 electron volts).

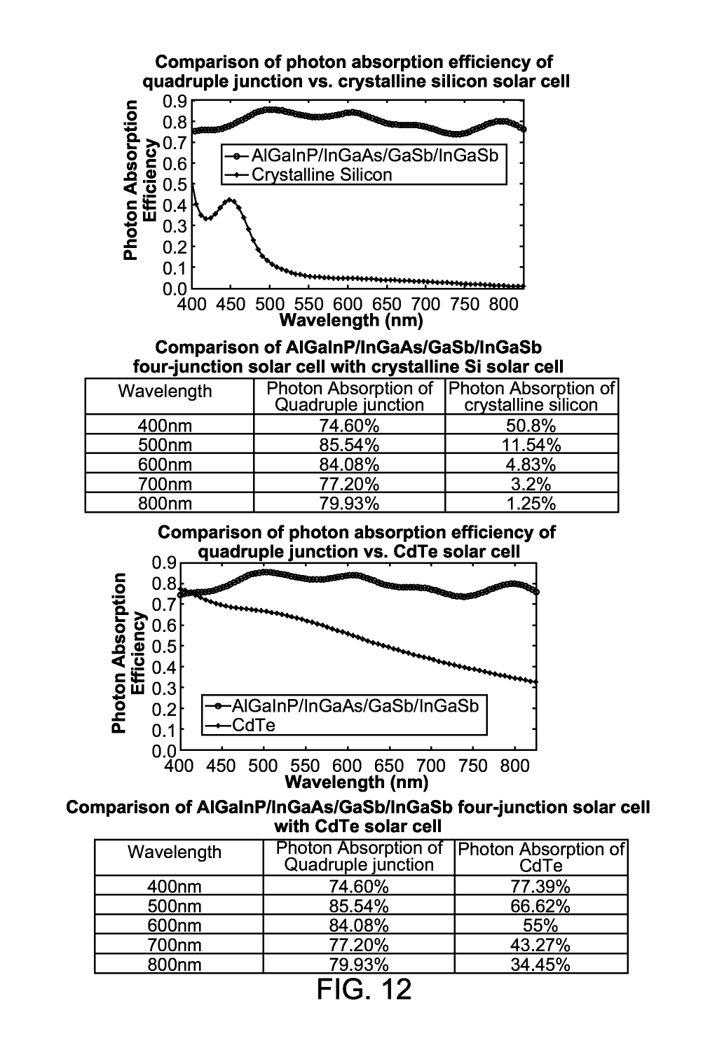

FIG. 12 is a graphical representation comparing the photon absorption efficiency of the four-junction solar cell of FIG. 11 with a crystalline silicon (Si) solar cell and with a cadmium telluride (CdTe) solar cell.

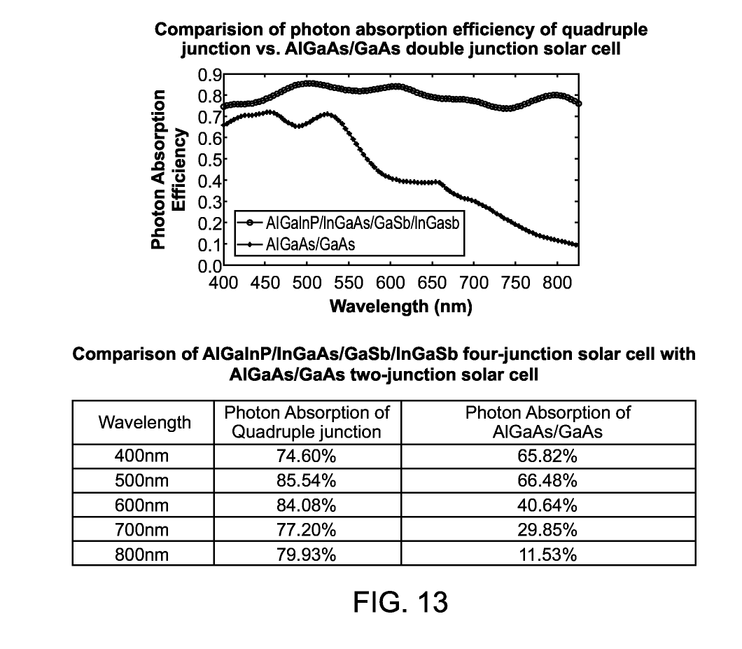

FIG. 13 is a graphical representation comparing the photon absorption efficiency of the four-junction solar cell of FIG. 11 with an aluminum gallium arsenide (AlGaAs)/gallium arsenide (GaAs) two-junction solar cell.

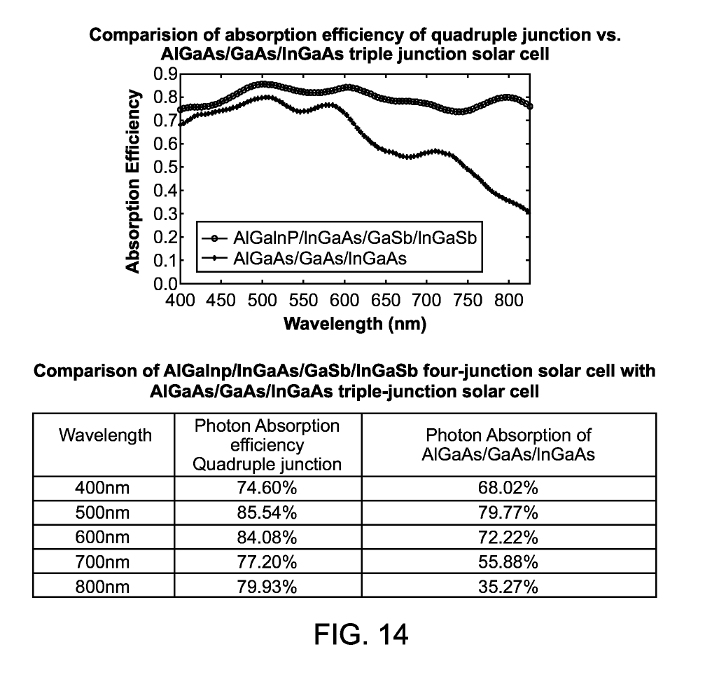

FIG. 14 is a graphical representation comparing the photon absorption efficiency of the four-junction solar cell of FIG. 11 with an aluminum gallium arsenide (AlGaAs)/gallium arsenide (GaAs)/indium gallium arsenide (InGaAs) triple-junction solar cell.

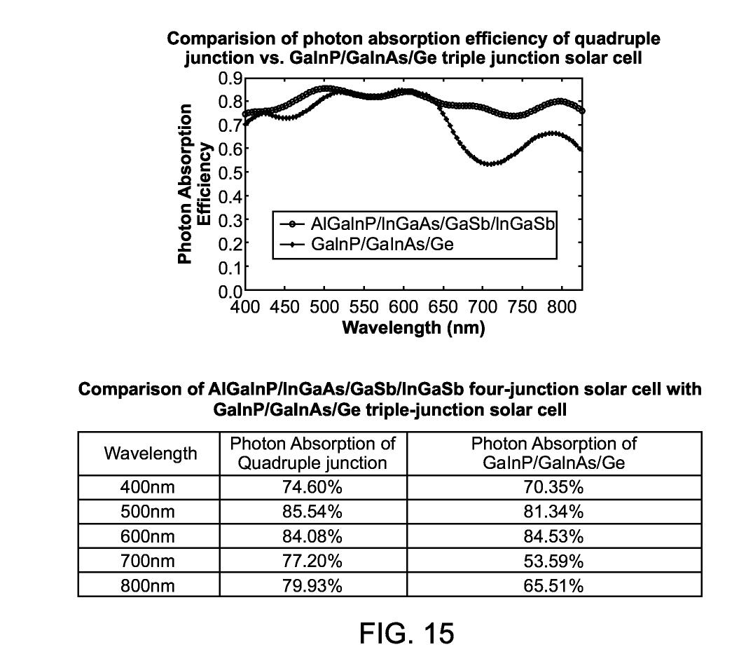

FIG. 15 is a graphical representation comparing the photon absorption efficiency of the four-junction solar cell of FIG. 11 with a gallium indium phosphide (GaInP)/gallium indium arsenide (GaInAs)/germanium (Ge) triple-junction solar cell.

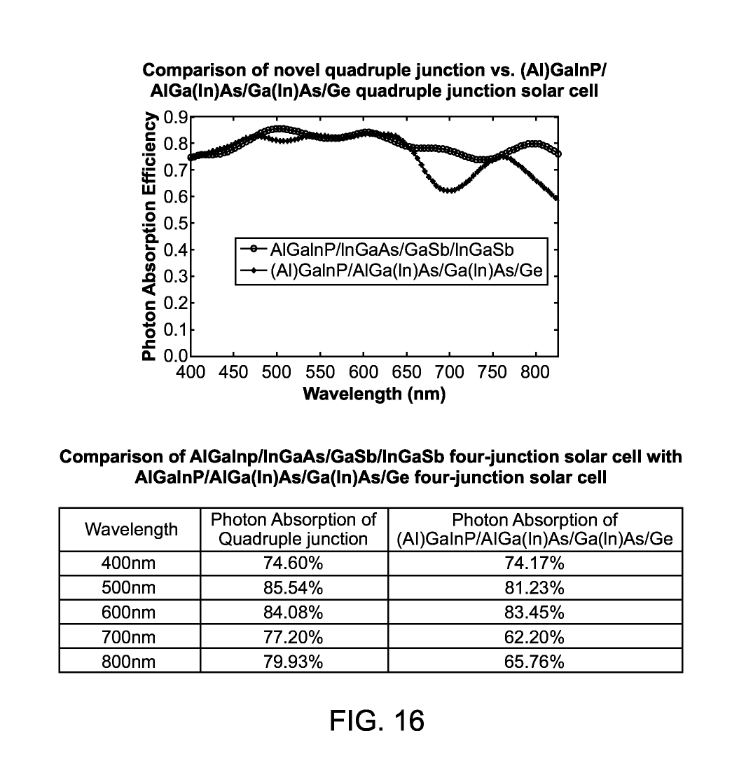

FIG. 16 is a graphical view comparing the photo absorption efficiency of the four-junction solar cell of FIG. 11 with an aluminum gallium indium phosphide (AlGaInP)/aluminum gallium indium arsenide (AlGa(In)As/gallium indium arsenide(Ga(In)As/germanium (Ge) four-junction solar cell.

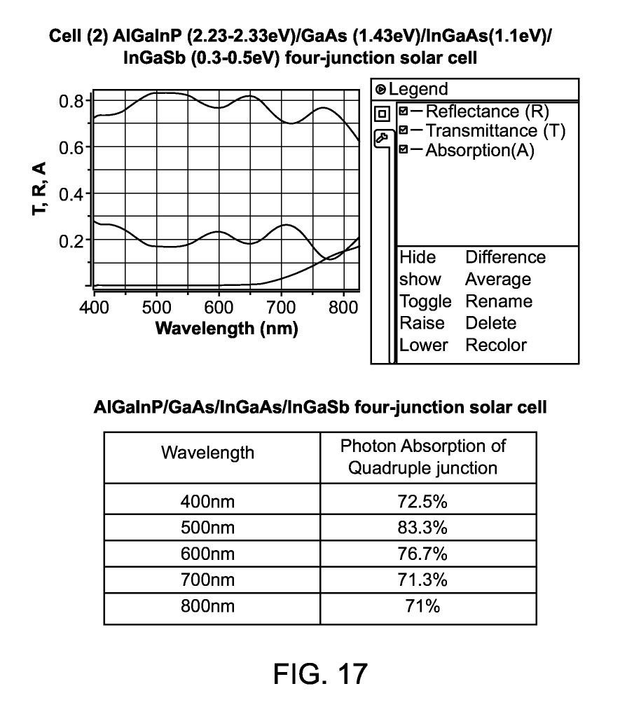

FIG. 17 illustrates the photon absorption efficiency of another embodiment of the solar cell of the present invention. This embodiment is a four-junction solar cell having as its junctions, aluminum gallium indium phosphide (AlGaInP) (with a band gap of between 2.23 and 2.33 electron volts), gallium arsenide (GaAs) (with a band gap of 1.43 electron volts), indium gallium arsenide (InGaAs) (with a band gap of 1.1 electron volts), and indium gallium antimonide (InGaSb) (with a band gap between 0.3 and 0.5 electron volts).

It is to be understood that while the invention in has been described in conjunction with the preferred specific embodiments thereof, that the foregoing description as well as the examples which follow are intended to illustrate and not limit the scope of the invention. Other aspects, advantages and modifications within the scope of the invention will be apparent to those skilled in the art to which the invention pertains.

We claim:

1. A solar cell comprising:
a first layer comprised of AlGaInP;
a second layer comprised of InGaAs;
a third layer comprised of GaSb;
a fourth layer comprised of InGaSb;
a first tunnel junction disposed between the first and second layers;
a second tunnel junction disposed between the second and third layers; and
a third tunnel junction disposed between the third and fourth layers.

2. The solar cell of claim 1, further comprising an antireflective coating situated on top of the first layer, the antireflective coating comprising one or another of MgO₂+TiO₂ and In₂O₃+SnO₂.

3. The solar cell of claim 1, wherein the first layer comprises:
an n⁺ AlGaInP emitter;
a p-type AlGaInP base; and
a p⁺ type AlGaInP back-surface-field layer.

4. The solar cell of claim 1, wherein the second layer comprises:
an n⁺ InGaAs emitter;
a p-type InGaAs base; and
a back-surface-field layer.

5. The solar cell of claim 1, wherein the third layer comprises:
an n⁺ GaSb emitter;
a p-type GaSb base; and
a p⁺ type GaSb back-surface-field layer.

6. The solar cell of claim 1, wherein the fourth layer comprises:
an n⁺ InGaSb emitter;
an InGaSb base; and
a p-type InGaSb substrate layer, the emitter and the base being formed on the substrate layer.

7. The solar cell of claim 1, wherein the first tunnel junction comprises:
a p⁺⁺ AlGaAs tunnel junction; and
an n⁺⁺ AlGaInP tunnel junction.

8. The solar cell of claim 1, wherein the second tunnel junction comprises:
a p⁺⁺ AlGaAs tunnel junction; and
a n⁺⁺ InGaAs tunnel junction.

9. The solar cell of claim 1, wherein the third tunnel junction comprises:
a p⁺⁺ AlGaAs tunnel junction; and
a n⁺⁺ GaSb tunnel junction.

10. A solar cell comprising:
a first layer comprised of AlGaInP;
a second layer comprised of InGaP;
a third layer comprised of InGaAs;
a fourth layer comprised of InGaSb;
a first tunnel junction disposed between the first and second layers;
a second tunnel junction disposed between the second and third layers; and
a third tunnel junction disposed between the third and fourth layers.

11. The solar cell of claim 10, wherein the first layer comprises:
an n⁺ AlGaInP emitter;
an AlGaInP base; and
a p⁺ AlGaInP back-surface-field layer.

12. The solar cell of claim 10, wherein the second layer comprises:
an n⁺ InGaP emitter;
a p-type InGaP base; and
a back-surface-field layer.

13. The solar cell of claim 10, wherein the third layer comprises:
an n⁺ In GaAs emitter;
a p-type InGaAs base; and
a back-surface-field layer.

14. The solar cell of claim 10, wherein the fourth layer comprises:
an n⁺ InGaSb emitter;
a p-type InGaSb base; and
a p-type InGaSb substrate layer, the emitter and the base being formed on the substrate layer.

15. A solar cell comprising:
a first layer comprised of AlGaInP;
a second layer comprised of GaAs;
a third layer comprised of InGaAs;
a fourth layer comprised of InGaSb;
a first tunnel junction disposed between the first and second layers;
a second tunnel junction disposed between the second and third layers; and
a third tunnel junction disposed between the third and fourth layers.

16. The solar cell of claim 15, wherein the second layer comprises:
an n⁺ GaAs emitter;
a p-type GaAs base; and
a 70 nm p⁺ GaAs back-surface-field layer.

17. The solar cell of claim 15, wherein the second tunnel junction comprises:
a p⁺⁺ AlGaAs tunnel junction; and
an n⁺⁺ GaAs tunnel junction.

18. The solar cell of claim 15, wherein the third layer comprises:
an n⁺ InGaAs emitter;
a p-type InGaAs base; and
a p⁺ type InGaAs back-surface-field layer.

19. The solar cell of claim 15, wherein the third tunnel junction comprises:
a p⁺⁺ AlGaAs tunnel junction; and
a n⁺⁺ InGaAs tunnel junction.

20. The solar cell of claim 15, wherein the fourth layer comprises:
a n⁺ nucleation layer;
an n⁺ InGaSb emitter;
a p-type InGaSb base; and
a p-type InGaSb substrate layer, wherein the nucleation layer, the emitter, and the base are developed over the substrate layer.
